(19) United States
(12) Patent Application Publication
(10) Pub. No.: US 2025/0327858 A1
(43) Pub. Date: Oct. 23, 2025

(54) Testing of Electronic Assemblies and Electronic Assemblies Having a Device for Testing

(71) Applicant: Siemens Aktiengesellschaft, München (DE)

(72) Inventors: Kai Kriegel, München (DE); Gerhard Mitic, München (DE); Christian Walbrecker-Baar, Karlsfeld (DE); Stefan Stegmeier, München (DE)

(73) Assignee: Siemens Aktiengesellschaft, München (DE)

(21) Appl. No.: 18/873,053

(22) PCT Filed: Jun. 2, 2023
(86) PCT No.: PCT/EP2023/064827

§ 371 Date: Dec. 9, 2024

(30) Foreign Application Priority Data
Jun. 8, 2022 (EP) 22177774.1

(51) Int. Cl. G01R 31/28; G01N 29/09; G01N 29/46

(52) U.S. Cl. CPC G01R 31/2894; G01N 29/09; G01N 29/46; G01N 2203/0051; G01N 2291/0289

(57) ABSTRACT

Various embodiments of the teachings herein include a method for quality testing an electronic assembly. An example includes: examining a component part of the electronic assembly including generating a electrical signal and exciting the examined component part using ultrasonic waves; evaluating resulting alterations in the electrical signal of using signal analysis; and determining material changes in the component part based on the evaluation.

### CROSS-REFERENCE TO RELATED APPLICATIONS

This application is a U.S. National Stage Application of International Application No. PCT/EP2023/064827 filed Jun. 2, 2023, which designates the United States of America, and claims priority to EP application Ser. No. 22/177,774.1 filed Jun. 8, 2022, the contents of which are hereby incorporated by reference in their entirety.

### TECHNICAL FIELD

The present disclosure relates to testing of electronic assemblies. Various embodiments of the teachings herein include methods and/or systems for testing electronic assemblies and electronic assemblies having a device for performing such a method.

### BACKGROUND

In the manufacture of electronic assemblies, in particular after the fitting-out of circuit carriers for electronic assemblies, quality control of the electronic assembly for manufacturing faults still has to be carried Regularly occurring manufacturing faults are defects. Such defects are, in particular, large-scale blowholes in solder joints, printed circuit board warping, insufficient soldering point contacting, delamination of conductor materials in printed circuit boards, flux residues, chip rotations and inadequate laser weld joints of metal load terminals.

It is known to examine electronic assemblies such as fitted-out circuit carriers for possible defects by means of optical imaging and/or electrical testing. However, visual quality control by means of automated imaging is not yet sufficiently reliable as regards some defects. In particular, printed circuit board warping can only be identified with difficulty by means of optical imaging. Large-scale blowholes, delamination of conductor materials in printed circuit boards and inadequate laser weld joints of metal load terminals cannot yet be identified in a sufficiently reliable manner optically and electrically.

However, quality control is also still necessary in the operation of electronic assemblies, in particular power-electronic assemblies, because operation-induced or aging-induced faults occur. Power-electronic systems such as power modules, for example, age primarily due to operation-related temperature cycles. Power-electronic systems and the power-switching modules thereof which are subject to high thermal loads, such as IGBT modules for example, undergo significant aging due to normal operation within their specified operational limits. IGBT modules are used in power-electronic converters, for instance.

This aging is brought about mainly by a high number of load cycles of the operational heating up and cooling down, which lead to the gradual destruction of chip solder layers under the semiconductor chips and to the fatigue of bonding wires and chip metallizations, which conduct the current into the switching and rectifying chips. Typical fault mechanisms are bond lift-off, that is to say lifting off until the bonding wire cracks, heel crack and solder fatigue of chip and system solder, which comprises the underlying solder of the ceramic carrier. One problem, amongst others, is that the point in time of an outage depends so much and in such a complicated manner on the previous loads that even advanced prediction models are very inaccurate.

In addition, aging also takes place in the chip periphery due to the temperature fluctuations. Therefore, on one hand, the circuit carrier (DCB, AMB) can be destroyed due to the different coefficients of expansion (ceramic/copper) over a shell fracture and on the other hand the overlying driver activation, in particular in future integrated power modules. Today, model-based estimation methods are used, for example, but these are very inaccurate. A further possibility is impedance spectroscopy, in which the thermal impedance of the module construction is determined. An electronic switch is used here as a heating element and as a sensor. This measurement can only be carried out if the system is not in operation. A further approach is distortion measurement with electrical excitation, which is caused by interfaces and transitions. These measurements are carried out with high frequency signals also in operation. The results require interpretation because the signals are very small.

In fields of use which are difficult to access or permanently in operation, in which an outage of a converter absolutely must be avoided, e.g. wind converters offshore or in traction applications, today there are various solutions for avoiding an unexpected operational shutdown as far as possible in organizational terms. Therefore, spontaneous shutdowns can be combated through redundancy of the power electronics or by actions at the maintenance level, for instance by preventive replacement of the power modules.

The service life to be expected, and the service life that has already passed, can be indicated with the aid of advanced thermal models on the basis of previous, accelerated service life tests. However, due to the high complexity of the dependencies, these calculations continue to be affected by very significant faults.

Some power module manufacturers offer IGBT power switching modules in whose IGBTs small measurement diodes are integrated as a temperature sensor. The growing temperature increase of the IGBT at a given operating current can then indirectly indicate (solder) aging. However, this is associated with chip area losses and higher chip costs.

### SUMMARY

Teachings of the present disclosure provide improved methods for testing an electronic assembly and electronic assemblies having a device for performing these methods. Various embodiments of the teachings herein allow testing an electronic assembly, in particular simple, inexpensive, and reliable testing of the electronic assembly. For example, some embodiments of the teachings herein include a method for quality testing an electronic assembly (10), in which at least one component part of the electronic assembly (10) is examined by means of an electrical characterization method, wherein the examined component part is excited by means of ultrasonic waves (130) in such a way that alterations in the signal of the electrical characterization method are caused thereby, which alterations are evaluated by means of a signal analysis (210) and indicate material changes in the component part.

In some embodiments, the electrical characterization method is an impedance spectroscopy and wherein the impedance spectra are compared by means of the signal analysis (210), wherein observed alterations in the impedance spectrum indicate damage to or delamination in the component part.

In some embodiments, a frequency-dependent impedance measurement is undertaken and wherein the signal analysis functionally interacts with the measurement, such that the measurement of the frequency-dependent impedance takes place in a comparative manner, once with and once without additional ultrasonic excitation, and the difference signals are evaluated.

In some embodiments, the ultrasonic waves (130) are generated by means of electrical excitation.

In some embodiments, the ultrasound signal portions are modulated onto the intermodulated electrical signal.

In some embodiments, a signal analysis is undertaken, by means of which thermomechanical portions and mechanical portions of the wear are separated.

In some embodiments, the electronic assembly (10) has a planar construction, and wherein the ultrasonic waves (130) are generated by means of an ultrasound generator (120) which is superimposed directly on planar AVT.

In some embodiments, the ultrasound generator (120) is integrated into the planar construction, in particular as a piezoelectric layer.

In some embodiments, the ultrasonic waves (130) are coupled as a near-surface wave into the electronic assembly (10).

In some embodiments, the ultrasonic waves (130) are generated as a volume wave within the electronic assembly (10).

In some embodiments, the electronic assembly (10) is set into ultrasonic vibration (110) continuously or once or at discrete points in time.

As another example, some embodiments include an electronic assembly (10), in particular a circuit carrier, configured to perform one or more of the methods described herein, comprising at least one ultrasound source (120) which is designed and arranged to set the power-electronic assembly (10) into ultrasonic vibration (110), comprising a measurement device (200) which is configured to undertake an electrical characterization, in particular a frequency-dependent impedance measurement, comprising an evaluation device (210) which is designed to indicate a defect in the electronic assembly (10) by means of the recorded electrical signal change.

In some embodiments, the assembly has a planar construction and has an ultrasound generator which is superimposed directly on planar AVT.

In some embodiments, assembly has a planar construction and has an ultrasound generator which is integrated into the planar construction, in particular as a piezoelectric layer.

In some embodiments, the assembly (10) has an ultrasound generator, which is integrated into a component of the electronic assembly (10), which component has piezoelectric properties, in particular as a piezoelectric layer.

### BRIEF DESCRIPTION OF THE DRAWINGS

Examples and embodiments of the teachings of the present disclosure are described further in an exemplary manner with reference to FIGS. 1 and 2 of the accompanying drawing:

FIG. 1 is a drawing showing a flowchart of an example method for measurement signal evaluation incorporating teachings of the present disclosure; and

FIG. 2 is a schematic drawing showing an example assembly having corresponding devices incorporating teachings of the present disclosure.

### DETAILED DESCRIPTION

An example method incorporating teachings of the present disclosure for quality testing an electronic assembly, in particular a power-electronic assembly, comprises examining at least one component part of the electronic assembly by means of an electrical characterization method, in which the examined component part is excited by means of ultrasonic waves in such a way that alterations signal in the of the electrical characterization method are caused thereby. The ultrasound-induced alterations in the electrical signal are evaluated by means of a signal analysis. Material changes in the component part are indicated as a result.

The example method accordingly implements condition monitoring on which a determination of the remaining service life can be based. Unplanned outages are avoided and predictive maintenance is made possible. Furthermore, the teachings herein may offer a commercial solution for the condition monitoring of entire power modules in converters, which is useful with regard to a prognosis of service life. The faults which can be detected by the specified quality control are, in particular, defects such as material defects for example, which can occur after manufacture but especially as a result of aging. In particular as a result of excessively high component part temperatures, and especially as a result of changes in temperature, damage is caused which can be detected with great certainty using the described methods. Accordingly, the methods may also be suitable for testing component parts or assemblies after manufacture to predict aging and assess outage risk on the basis of the results of a test after manufacture. They can be used in the operation of the electronic component or the electronic assembly. A test which can be undertaken in operation and a test which can be undertaken repeatedly may offer particular advantages for the prediction of aging or assessment of outage risk which can be derived therefrom.

An electronic assembly means a power-electronic assembly, e.g. a power module. An electronic assembly comprises at least one component part, in particular a semiconductor component, e.g. a semiconductor switch. The construction of an electronic assembly accordingly comprises different layers and generally different materials, which are also produced and assembled by means of different manufacturing methods. Material changes can be understood to mean damage, delamination, cracks, and generally material aging.

Typical components of power electronics may include, but not limited to: bipolar power transistors such as switch mode power supplies and DC/DC converters, power MOSFETs, IGBTs, in particular switch mode power supplies, motor controllers and converters, moreover thyristors, power converters, solid state relays, pulse current sources, activators of thyristors, GTO thyristors, high-output power converters, triacs, dimmers or solid state relays, diodes for rectification and as free-wheeling diodes, for example Schottky diodes or silicon diodes, and/or power capacitors.

Fields of use of power electronics can be, but are not limited to, switch mode power supplies, frequency converters, high-frequency generators, direct current regulators, phase angle controllers, high-voltage direct current transmission, inverters or solid state relays.

The measurement is possible not only during operation and repeatedly during operation, but even continuous measurement of the aging is made possible. Therefore, the condition of an entire module construction can be continuously measured in operation, and necessary actions can be deduced therefrom. This solution can be used commercially for monitoring the condition of entire power modules in converters. The specified quality testing method is reliable with regard to service life prediction.

The teachings herein make it possible to have improved, non-destructive, more reliable detection of aging-induced damage or delamination in a power-electronic assembly that can be undertaken when a component part is in operation and in individual component parts of this assembly, especially power modules of power-electronic appliances. The assembly and component parts of the assembly can also be examined, in optically inaccessible areas, for manufacturing faults after fitting-out.

Impedance spectroscopy may be used as an electrical characterization method. In some embodiments, at least one component part of the power-electronic assembly is examined by measuring at least one impedance spectrum of the component part and the change therein as a result of the ultrasonic excitation. The impedance spectra are compared by means of the signal analysis, wherein observed alterations indicate damage to or delamination in the component part. In particular, the signal analysis functionally interacts with the measurement: The measurement of the frequency-dependent impedance takes place in a comparative manner, once with and once without additional US excitation. The difference signals are evaluated.

In electrical distortion measurement, due to non-linear electrical, thermal and mechanical properties, high-frequency signals are produced during high-frequency transmission in power-electronic systems, which signals deviate significantly from the original frequency. signals Frequency are produced which correspond to a multiple of the original frequency or, at feed-in, correspond to multiple frequencies of a difference frequency or sum frequency.

In some embodiments, the ultrasonic waves are generated by means of electrical excitation. For example, an ultrasound signal is coupled by means of electrical excitation into the component part to be characterized, or into the assembly. There is then electrical distortion at the interfaces of the connecting layers (solder, bonding or similar) as a result of non-linear effects based on local temperatures, mechanical delamination and electrical transition resistances.

In some embodiments, the ultrasound signal portions are modulated onto the intermodulated electrical signal. Electrical signal means the output signal of the electrical characterization method. This provides that faults in the tested construction are initially amplified and thereby more easily identifiable.

In some embodiments, a signal analysis is undertaken, by means of which thermomechanical portions and mechanical portions of the wear are separated. This is possible because, as a result of the ultrasound signal, primarily the mechanical signals which give the indications of defects are amplified.

In some embodiments, an electronic assembly is examined which has a planar construction and which generates ultrasonic waves by means of an ultrasound generator which is superimposed directly on planar AVT. AVT is to be understood as a planar construction in construction and connection technology. An ultrasound generator may be integrated directly into the planar construction, in particular as a piezoelectric layer. In one of these described embodiments, the ultrasonic waves are coupled as a near-surface wave into the power-electronic assembly, for example.

In some embodiments, the ultrasonic waves can be generated as a volume wave within the electronic assembly. In particular, for this purpose the ultrasonic waves are generated at multiple positions on the power-electronic assembly. For this purpose, there are in particular multiple ultrasound generators in the planar construction.

In some embodiments, the electronic assembly is set into ultrasonic vibration continuously or once or at discrete points in time.

In some embodiments, a power-electronic assembly, in particular a circuit carrier, is configured to perform one or more of the methods described herein. For this purpose, the assembly comprises at least one ultrasound source which is designed and arranged to set the electronic assembly into ultrasonic vibration, a measurement device which is configured to undertake an electrical characterization, in particular a frequency-dependent impedance measurement, and an evaluation device which is designed to indicate a defect in the electronic assembly by means of the recorded electrical signal change.

In some embodiments, the assembly comprises a power-electronic assembly, in particular a circuit carrier, i.e. at least one component part of the assembly is a power switch. For example, a spectrum analyzer or lock-in amplifier can be used as a measuring device which is configured to undertake a frequency-dependent impedance measurement.

In some embodiments, the electronic assembly has a planar construction and comprises an ultrasound generator which is superimposed directly on planar AVT. For example, a piezo actuator or a sonotrode can be used for the near-surface ultrasound signal irradiation.

In some embodiments, the electronic assembly has a planar construction and comprises an ultrasound generator which is integrated into the planar construction, in particular as a piezoelectric layer. Silicon carbide semiconductors or silicon carbide MOS (metal oxide semiconductors) or gallium nitride are used as ultrasound generators.

In some embodiments, the electronic assembly has an ultrasound generator integrated into a component of the power-electronic assembly, which component has piezoelectric properties, in particular as a piezoelectric layer. That is to say at least one ultrasound generator is comprised, which represents a component of the power-electronic assembly in a further function, which component comprises a piezoelectric layer.

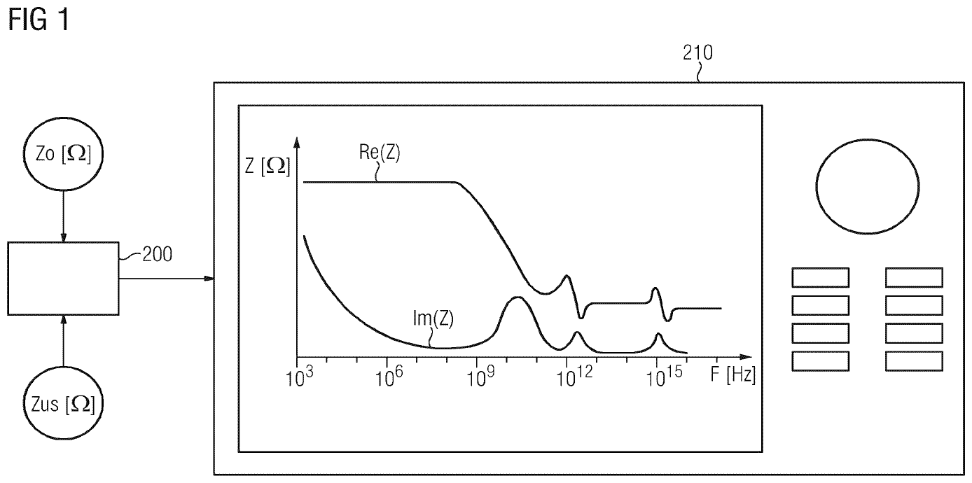

In an example method for testing an electronic assembly 10, the electronic assembly 10 is set into ultrasonic vibration 110. Ultrasonic vibration 110 regularly extends over a frequency range from 10 to 300 kHz. At the same time, the electronic assembly 10 is examined by means of an electrical characterization method, in particular impedance spectroscopy. The impedance spectrum Zᵤₛ [Ω], altered by ultrasonic vibration 110, of the electronic assembly 10, or of only one electronic connection 80, 90 or one component part 50, 60 may be recorded and employed in order to indicate a defect. For the evaluation 210, the altered impedance spectrum Zᵤₛ [Ω] is compared with the impedance spectrum without ultrasonic excitation Zₒ [Ω], as shown schematically in the flowchart of FIG. 1. This measurement signal evaluation preferably takes place in an evaluation unit 210, which is configured to receive and evaluate the electrical measurement signals. By means of the specified method, electronic assemblies 10 can be tested for defects, such as in particular for local bad spots 95, which cannot be recorded with optical or electronic methods such as those known from the prior art.

In some embodiments, the electronic assembly 10 may be set into ultrasonic vibration 110 once. For this purpose, the electronic assembly 10 may be excited by means of a time-limited ultrasonic wave train and thus set into vibration. In some embodiments, the electronic assembly 10 can be set repeatedly into ultrasonic vibration at discrete points in time. For example, multiple time-localized ultrasonic wave trains are used for this purpose. In this way, transient ultrasonic vibration 110 in the electronic assembly 10 can also be evaluated. Information regarding local attenuation and natural resonance can be obtained in particular from transient ultrasonic vibration 110.

In some embodiments, the electronic assembly 10 can also be set into ultrasonic vibration 110 continuously. Therefore, particularly changes in the resonant frequencies of natural vibration in the electronic assembly 10 or parts of the electronic assembly 50, 60, 80, 90 can be employed in order to indicate the presence of defects and/or the location 95 of such defects. The electronic assembly 10 may be set into ultrasonic vibration 110 in multiple regions 120 of the electronic assembly 10. Therefore, setting the electronic assembly 10 into ultrasonic vibration 110 in multiple regions of the electronic assembly 10 can give information regarding a spatial localization of defects 95. In addition, it can be ensured that all relevant natural vibration of the electronic assembly 10 is excited if the electronic assembly 10 is set into ultrasonic vibration 110 not only in a single region. The reliability of the methods described herein may be consequently increased further in this development.

In particular, faulty connections 80, 90 of different materials result in altered vibration behavior of the electronic assembly 10 in ultrasonic vibration 110. Especially a large-scale solder joint 80, 90 of component parts 50, 60 or laser welds of load terminals have altered vibration behavior in the case of defects. Also and specifically defective metallizations 40 of circuit carriers 20 or warping of circuit carriers 20 can be easily recorded by means of the methods described herein. It is consequently possible to test electronic assemblies 10 particularly reliably.

For example, the electronic assembly 10 may be a circuit carrier, or the electronic assembly has a circuit carrier 20. An electronic assembly 10 is often composed of various components 50, 60, or component parts and accordingly composed of various materials, in particular materials from construction and connection technology, in which materials defects in the form of cavities, cracks or partial detachment of the connection regularly occur. In this way, a test for defects can take place reliably and efficiently specifically in this important case of electronic assemblies 10 comprising circuit carriers 20.

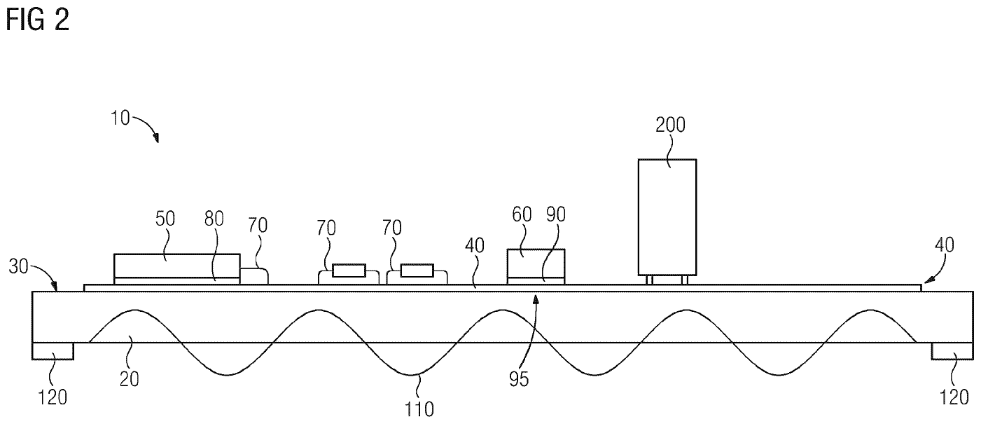

FIG. 2 shows a basic schematic diagram of an electronic assembly 10, which is arranged and designed to perform one or more of the methods described herein for testing the electronic assembly 10. The electronic assembly 10 comprises, for example, an ultrasound source 120 which is designed and arranged to set the electronic assembly 10 into ultrasonic vibration 110. In addition, the electronic assembly 10 comprises a device 200 for carrying out an impedance measurement or electrical contacts for connecting a device 200 for carrying out an impedance measurement. An evaluation device 210, which is not depicted in FIG. 2 because it does not necessarily have to be structurally connected to the assembly 10, indicates a defect 95 in the electronic assembly 10 by means of the impedance spectroscopy Zᵤₛ [Ω] which is influenced by ultrasonic waves.

The method may be carried out to test an electronic assembly in the form of a power module 10. The power module 10 has a circuit carrier in the form of a printed circuit board 20, which is formed as a flat part having a flat side 30. On the flat side 30, there is a copper metallization in the form of a copper layer 40 connected in a planar manner. Semiconductor components 50, 60 and a load terminal 70 are connected to the copper layer 40. The semiconductor components 50, 60 are connected to the copper metallization 40 by means of solder layers 80, 90. The load terminal 70 is welded to the copper metallization 40 by means of a laser weld 100. In the solder layers 80, 90, by means of which the semiconductor components 50, 60 are connected to the copper metallization 40 and in the laser weld 100, by means of which the load terminal 70 is connected to the copper metallization 40, defects occur in the form of cavities, such as blowholes or delamination. To test the power module 10 for these defects, the power module 10 is set into ultrasonic vibration 110. For this purpose, ultrasound sources 120 are provided which irradiate ultrasonic waves 130 onto the printed circuit board 20 in the direction 140 perpendicular to the flat side 30 onto a side of the printed circuit board 20 facing away from the flat side 30. The ultrasound sources 120, viewed in the planar directions of extension of the flat side 30, are arranged at mutually remote ends of the flat side 30 of the printed circuit board 20. The power module 10 is therefore set into ultrasonic vibration 110 in multiple regions.

Aging in the power module becomes noticeable as a result of altered vibration behavior of the bonding wires 70 and soldered chips 50, 60, since these connections 80, 90 loosen as a result of delamination. The vibration loading by the ultrasound 110 engages such delamination, amplifies the signals and produces in particular additional signals if delamination occurs and expands. Therefore, in the case of cracks for example, the US portions can be modulated onto the electrical signal. As a result of a signal analysis 210, the thermal portions and the mechanical portions can be separated. This can be particularly advantageous in planar construction and connection technology (in German: Aufbau-und Verbindungstechnik (AVT)), since a US transmitter 120 can easily couple into the planar construction. The US transmitter 120 is then superimposed on planar AVT and can couple the ultrasonic waves 110 into the planar construction. The US transmitter 120 comprises piezoelectric layers which can also be integrated into planar construction and connection technology. It should be noted here that the ultrasound 110 can be coupled in as a near-surface wave but can also be generated as a volume wave in the component part to be examined.

In some embodiments, a power component part 50, 60 itself can function as a US transmitter 120 and receiver, since in particular SiC and GaN semiconductors possess piezoelectric properties. The ultrasound transmitters 120 are also then present integrated in the power module 10. As a result of appropriate electrical excitation, the component part 50, 60 can emit ultrasound signals 110 and detect returning signals. The additional mechanical stimulation by means of ultrasound 110 can be achieved particularly simply in planar constructions. As a result, delamination and cracks can be identified more easily. In comparison to existing testing methods, such as HF reflectometry for example, the proposed method is wired, at significantly lower frequencies. Piezo actuators for US stimulation 120 can be integrated directly in planar construction technology or the power component parts 50, 60 themselves take over this function. A relatively high degree of measurement accuracy, optionally with local resolution, depending on how many ultrasound generators 120 and sensors are used and in what distribution. Furthermore, the proposed measurement technology is relatively inexpensive and the proposed method enables early detection of the extent and nature of an instance of thermomechanical aging.

### LIST OF REFERENCE SIGNS

110 ultrasonic vibration
120 ultrasound source
130 ultrasonic waves
140 direction of the ultrasonic waves
10 electronic assembly, power module
20 printed circuit board
30 flat side
40 copper layer
50 semiconductor component
60 semiconductor component
70 bonding wires, solder joints
80 solder layer
90 solder layer
95 local bad spot
100 laser weld
Zᵤₛ [Ω] impedance with ultrasonic excitation
Zₒ [Ω] impedance without ultrasonic excitation
200 receiving unit, measurement unit for impedance
210 evaluation unit

What is claimed is:

1. A method for quality testing an electronic assembly, the method comprising:
examining a component part of the electronic assembly including generating a electrical signal and exciting the examined component part using ultrasonic waves;
evaluating resulting alterations in the electrical signal of using signal analysis; and
determining material changes in the component part based on the evaluation.

2. The method as claimed in claim 1, wherein:
the electrical signal is generated as part of impedance spectroscopy;
the signal analysis compares impedance spectra; and
alterations in the impedance spectra indicate damage to or delamination in the component part.

3. The method as claimed in claim 2, wherein:
the impedance spectroscopy includes frequency-dependent impedance measurement;
the signal analysis functionally interacts with the measurement, such that the measurement of the frequency-dependent impedance takes place in a comparative manner, once with and once without additional ultrasonic excitation; and
the difference signals are evaluated.

4. The method as claimed in claim 1, wherein the ultrasonic waves are generated by electrical excitation.

5. The method as claimed in claim 1, further comprising modulating the ultrasound signal portions onto the intermodulated electrical signal.

6. The method as claimed in claim 1, wherein the signal analysis separates thermomechanical portions and mechanical portions of component wear.

7. The method as claimed in claim 1, wherein:
the electronic assembly has a planar construction; and
the ultrasonic waves are generated by an ultrasound generator superimposed directly on planar AVT.

8. The method as claimed in claim 7, wherein the ultrasound generator is integrated into the planar construction.

9. The method as claimed in claim 7, wherein the ultrasonic waves are coupled as a near-surface wave into the electronic assembly.

10. The method as claimed in claim 1, wherein the ultrasonic waves are generated as a volume wave within the electronic assembly.

11. The method as claimed in claim 1, wherein the electronic assembly is set into ultrasonic vibration continuously or once or at discrete points in time.

12. An electronic assembly comprising:
an ultrasound source to set the electronic assembly into ultrasonic vibration;
a measurement device to undertake an electrical characterization; and
an evaluation device to indicate a defect in the electronic assembly using an electrical signal change.

13. The electronic assembly as claimed in claim 12, with a planar construction and further comprising an ultrasound generator superimposed directly on planar AVT.

14. The electronic assembly as claimed in claim 12, with a planar construction and further comprising an ultrasound generator integrated into the planar construction.

15. The electronic assembly as claimed in claim 12, including an ultrasound generator integrated into a component of the electronic assembly with piezoelectric properties.
